(19) United States
(12) Patent Application Publication
(10) Pub. No.: US 2025/0337373 A1
(43) Pub. Date: Oct. 30, 2025

(54) DISTRIBUTION CIRCUIT, RECEPTION DEVICE, AND TRANSMISSION/RECEPTION DEVICE

(71) Applicant: Sony Semiconductor Solutions Corporation, Kanagawa (JP)

(72) Inventors: Masayoshi Abe, Tokyo (JP); Naoto Yoshikawa, Tokyo (JP); Fuminori Koga, Fukuoka (JP)

(21) Appl. No.: 18/870,105

(22) PCT Filed: Apr. 13, 2023
(86) PCT No.: PCT/JP2023/014992

§ 371 Date: Nov. 27, 2024

(30) Foreign Application Priority Data
Jun. 7, 2022 (JP) 2022-091953

(51) Int. Cl. H03F 3/19

(52) U.S. Cl. CPC H03F 3/19; H03F 2200/294; H03F 2200/451

(57) ABSTRACT

Reduced circuit area in a reception device that distributes wireless signals is disclosed. In one example, a low noise amplifier includes an input matching circuit that converts an input impedance of a downstream circuit, and an amplifier circuit that amplifies a wireless signal received from the input matching circuit. A power splitter includes a first output matching circuit that converts a first load impedance into a first impedance related to a load impedance ZL of the low noise amplifier, and a second output matching circuit that converts a second load impedance into a second impedance related to the ZL.

### TECHNICAL FIELD

The present technology relates to a distribution circuit. More specifically, the present technology relates to a distribution circuit, a reception device, and a transmission/reception device that receive wireless signals.

### BACKGROUND ART

In the related art, for a television tuner, a wireless transmission/reception device, or the like, a power splitter is used to distribute a wireless signal received via an antenna to a plurality of reception circuits. For example, a wireless transmission/reception device using a Wilkinson splitter as a power splitter has been proposed (see, for example, Patent Document 1). Furthermore, to increase reception sensitivity, a low noise amplifier is used upstream of the power splitter (see, for example, Patent Documents 2 and 3).

### CITATION LIST

### Patent Document

Patent Document 1: Japanese Translation of PCT International Application Publication No. 2009-544206
Patent Document 2: Japanese Patent Application Laid-Open No. 2007-36863
Patent Document 3: U.S. Patent Application Publication No. 2015/0055021

### SUMMARY OF THE INVENTION

### Problems to be Solved by the Invention

In the related art described above, the Wilkinson splitter is used to simplify a distribution circuit. The above-described Wilkinson splitter, however, requires a plurality of transmission lines of ¼ wavelength, which makes it difficult to reduce the circuit area of the splitter.

The present technology has been made in view of such circumstances, and it is therefore an object of the present technology to reduce a circuit area in a reception device that distributes a wireless signal.

### Solutions to Problems

The present technology has been made to solve the above-described problems, and a first aspect of the present technology is a distribution circuit including: a low noise amplifier including an input matching circuit that converts an input impedance of a downstream circuit, and an amplifier circuit that amplifies a wireless signal received from the input matching circuit; and a power splitter including a first output matching circuit that converts a first load impedance into a first impedance related to a load impedance ZL of the low noise amplifier, and a second output matching circuit that converts a second load impedance into a second impedance related to the ZL. This brings about an effect of reducing the circuit area.

Furthermore, in the first aspect, the power splitter may further include: a first resistive element interposed between an output terminal of the low noise amplifier and an input terminal of the first output matching circuit; and a second resistive element interposed between the output terminal of the low noise amplifier and an input terminal of the second output matching circuit, the ZL may be approximately in a complex conjugate relationship with an output impedance Zao of the low noise amplifier, the ZL may correspond to an equivalent impedance of a circuit in which a predetermined number of input impedances including a first input impedance Zᵢₙ₁ and a second input impedance Zᵢₙ₂ are connected in parallel, the first impedance may be approximately in a complex conjugate relationship with an output impedance Zr1 as viewed from output of the first resistive element, the Zr1 may correspond to a sum of a resistance value of the first resistive element and an equivalent impedance of an input impedance of each system other than the Zᵢₙ₁ and the Zao, the second impedance may be approximately in a complex conjugate relationship with an output impedance Zr2 as viewed from output of the second resistive element, and the Zr2 may correspond to a sum of a resistance value of the second resistive element and an equivalent impedance of an input impedance of each system other than the Zᵢₙ₂ and the Zao. The use of the first resistive element and the second resistive element brings about an effect of reducing the impedance conversion ratio of the output matching circuit.

Furthermore, in the first aspect, the low noise amplifier may have an output terminal connected to both input terminals of the first and second output matching circuits, the ZL may be approximately in a complex conjugate relationship with an output impedance Zao of the low noise amplifier, the ZL may correspond an equivalent impedance of a circuit in which a predetermined number of input impedances including a first input impedance Zᵢₙ₁ and a second input impedance Zᵢₙ₂ are connected in parallel, the first impedance may correspond to the Zᵢₙ₁, and the second impedance corresponds to the Zᵢₙ₂. This brings about an effect of reducing the number of resistive elements.

Furthermore, in the first aspect, the power splitter may further include: a first resistive element having one end connected to an output terminal of the first output matching circuit; and a second resistive element having one end connected to an output terminal of the second output matching circuit. This brings about an effect of reducing the output return loss.

Furthermore, in the first aspect, the first and second output matching circuits may each include at least one of an inductive element, a capacitive element, or a resistive element. This brings about an effect of achieving impedance matching in high-frequency circuits.

Furthermore, a second aspect of the present technology is a reception device including: a low noise amplifier including an input matching circuit that converts an input impedance of a downstream circuit, and an amplifier circuit that amplifies a wireless signal received from the input matching circuit; a power splitter including a first output matching circuit that converts a first load impedance into a first impedance related to a load impedance ZL of the low noise amplifier, and a second output matching circuit that converts a second load impedance into a second impedance related to the ZL; a first receiver that demodulates a signal output from an output terminal of the first output matching circuit; and a second receiver that demodulates a signal output from an output terminal of the second output matching circuit. This brings about an effect of reducing the circuit area of the reception device.

Furthermore, a third aspect of the present technology is a transmission/reception device including: a low noise amplifier including an input matching circuit that converts an input impedance of a downstream circuit, and an amplifier circuit that amplifies a wireless signal received from the input matching circuit; a power splitter including a first output matching circuit that converts a first load impedance into a first impedance related to a load impedance ZL of the low noise amplifier, and a second output matching circuit that converts a second load impedance into a second impedance related to the ZL; a first receiver that demodulates a signal output from an output terminal of the first output matching circuit; a second receiver that demodulates a signal output from an output terminal of the second output matching circuit; and a transmitter that generates a transmit signal. This brings about an effect of reducing the circuit area of the transmission/reception device.

### BRIEF DESCRIPTION OF DRAWINGS

FIG. 1 is a block diagram illustrating a configuration example of a reception system according to a first embodiment of the present technology.

FIG. 2 is a block diagram illustrating a configuration example of a multi-tuner according to the first embodiment of the present technology.

FIG. 3 is a block diagram illustrating a configuration example of a multi-output LNA according to the first embodiment of the present technology.

FIG. 4 is a circuit diagram illustrating a configuration example of an input matching circuit according to the first embodiment of the present technology.

FIG. 5 is a circuit diagram illustrating a configuration example of an active amplifier circuit according to the first embodiment of the present technology.

FIG. 6 is a circuit diagram illustrating a configuration example of an output matching circuit according to the first embodiment of the present technology.

FIG. 7 is a block diagram illustrating a configuration example of a receiver according to the first embodiment of the present technology.

FIG. 8 is a block diagram illustrating a configuration example of a multi-output LNA according to a comparative example.

FIG. 9 is a diagram for comparing a footprint of the first embodiment of the present technology with a footprint the comparative example.

FIG. 10 is a graph showing an example of a gain by frequency according to the first embodiment of the present technology and the comparative example.

FIG. 11 is a graph showing an example of inter-output terminal isolation by frequency according to the first embodiment of the present technology and the comparative example.

FIG. 12 is a graph showing an example of output return loss by frequency according to the first embodiment of the present technology and the comparative example.

FIG. 13 is a diagram showing a comparison result of characteristics between the first embodiment of the present technology and the comparative example.

FIG. 14 is a block diagram illustrating a configuration example of a multi-output LNA according to a second embodiment of the present technology.

FIG. 15 is a block diagram illustrating a configuration example of a multi-output LNA according to a third embodiment of the present technology.

FIG. 16 is a block diagram illustrating a configuration example of a transmission/reception device according to a fourth embodiment of the present technology.

FIG. 17 is a block diagram illustrating a schematic configuration example of a vehicle control system.

FIG. 18 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First embodiment (example where a plurality of output matching circuits is provided in a power splitter)
2. Second embodiment (example where a plurality of output matching circuits is provided in a power splitter and the number of resistive elements is reduced)
3. Third embodiment (example where a plurality of output matching circuits is provided in a power splitter and a resistive element is arranged on an output side)
4. Fourth embodiment (example where a plurality of output matching circuits is provided in a power splitter in a transmission/reception device)
5. Example of application to mobile body

### 1. First Embodiment

### [Configuration Example of Reception System]

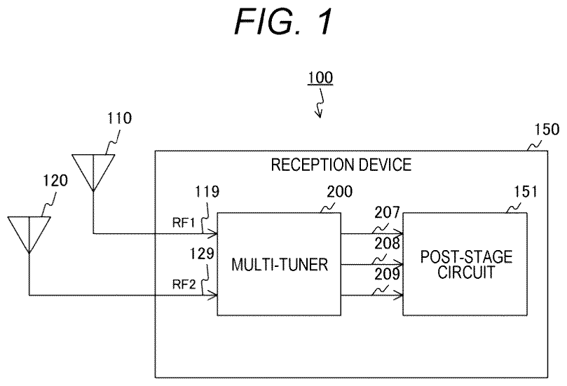

FIG. 1 is a block diagram illustrating a configuration example of a reception system 100 according to a first embodiment of the present technology. The reception system 100 receives a wireless signal such as a digital terrestrial broadcast signal, and includes antennas 110 and 120 and a reception device 150. Examples of the reception device 150 include a television tuner, a television receiver, a cable TV set top box, a recorder, and the like.

The antennas 110 and 120 are each configured to convert a radio frequency (RF) signal, which is an electromagnetic wave, arriving over the air into an electric signal. The antenna 110 receives, for example, a digital terrestrial broadcast signal RF1 as the RF signal and supplies the digital terrestrial broadcast signal RF1 to the reception device 150 through an antenna cable 119. The antenna 120 receives, for example, a satellite broadcast signal RF2 as the RF signal and supplies the satellite broadcast signal RF2 to the reception device 150 through an antenna cable 129.

The reception device 150 includes a multi-tuner 200 and a post-stage circuit 151. Note that, although the digital terrestrial broadcast signal RF1 and the satellite broadcast signal RF2 are transmitted through different antenna cables, it is also possible to transmit the digital terrestrial broadcast signal RF1 and the satellite broadcast signal RF2 through one antenna cable. In this case, a duplexer is additionally provided upstream of the multi-tuner 200 in the reception device 150.

The multi-tuner 200 is configured to distribute and demodulates the digital terrestrial broadcast signal RF1 and the satellite broadcast signal RF2 to generate a plurality of (for example, three) demodulated signals. The multi-tuner 200 supplies the three demodulated signals to the post-stage circuit 151 through signal lines 207, 208, and 209.

The post-stage circuit 151 is configured to decode and process the demodulated signals. In the post-stage circuit 151, in addition to a decoder, a storage device, a display device, a speaker, or the like is arranged. For example, in a case where the reception device 150 is a recorder, a decoder and a storage device are arranged in the post-stage circuit 151. Furthermore, in a case where the reception device 150 is a television receiver, a display device and a speaker are further arranged in the post-stage circuit 151.

### [Configuration Example of Multi-Tuner]

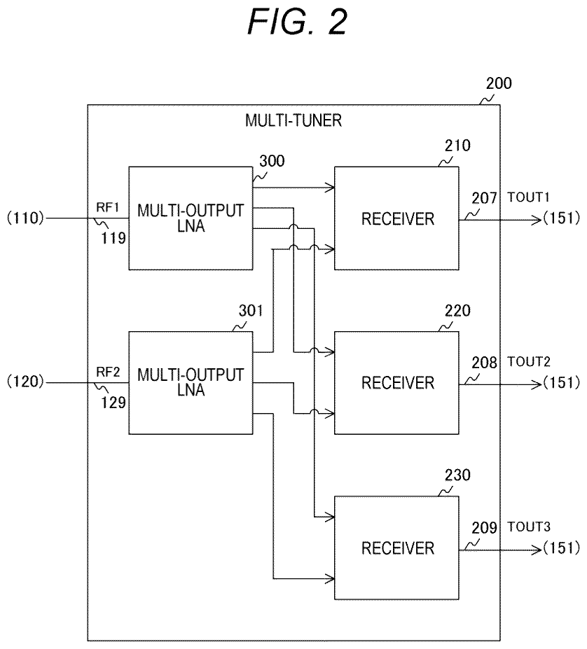

FIG. 2 is a block diagram illustrating a configuration example of the multi-tuner 200 according to the first embodiment of the present technology. The multi-tuner 200 includes multi-output LNAs 300 and 301 and receivers 210, 220 and 230.

The multi-output LNA 300 is configured to distribute the digital terrestrial broadcast signal RF1 to the receivers 210, 220, and 230. The multi-output LNA 301 is configured to distribute the satellite broadcast signal RF2 to the receivers 210, 220, and 230. Note that the multi-output LNA 300 is an example of a distribution circuit described in the claims.

The receivers 210, 220, and 230 are each configured to demodulate either the digital terrestrial broadcast signal RF1 or the satellite broadcast signal RF2. The receiver 210 generates a demodulated signal TOUT1 and supplies the demodulated signal TOUT1 to the post-stage circuit 151 through the signal line 207. The receiver 220 generates a demodulated signal TOUT2 and supplies the demodulated signal TOUT2 to the post-stage circuit 151 through the signal line 208. The receiver 230 generates a demodulated signal TOUT3 and supplies the demodulated signal TOUT3 to the post-stage circuit 151 through the signal line 209.

Note that although two RF signals (the digital terrestrial broadcast signal RF1 and the satellite broadcast signal RF2) are input into the multi-tuner 200, it is also possible to input only one of the signals. In this case, one of the multi-output LNAs 300 and 301 becomes unnecessary. Furthermore, it is also possible to input three or more RF signals into the multi-tuner 200. In this case, the number of multi-output LNAs is increased on the basis of the number of RF signals.

Furthermore, although the multi-tuner 200 generates three demodulated signals, the multi-tuner 200 can generate two demodulated signals. In this case, any one of the receivers 210, 220, and 230 becomes unnecessary. Alternatively, the multi-tuner 200 can generate four or more demodulated signals. In this case, the number of receivers is increased on the basis of the number of demodulated signals.

### [Configuration Example of Multi-Output LNA]

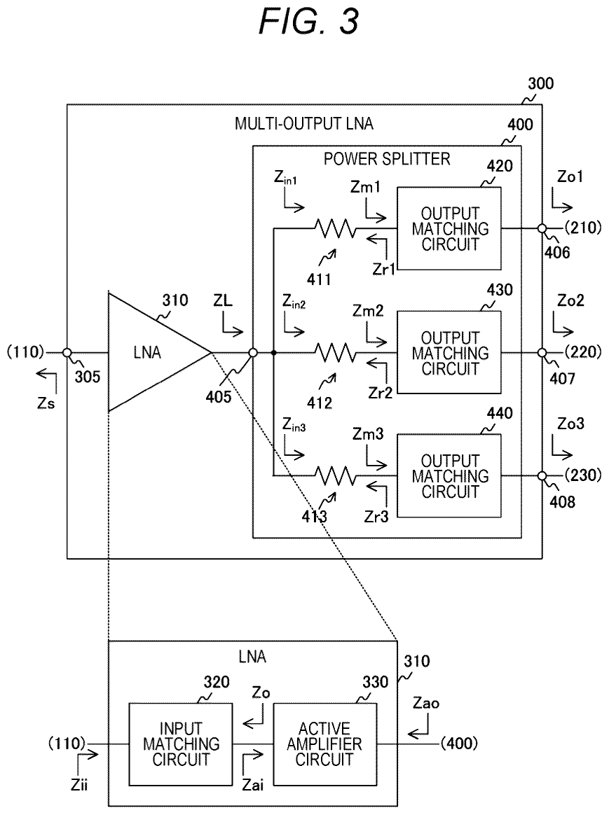

FIG. 3 is a block diagram illustrating a configuration example of the multi-output LNA 300 according to the first embodiment of the present technology. The multi-output LNA 300 includes an LNA 310 and a power splitter 400. Note that the multi-output LNA 301 is similar in configuration to the multi-output LNA 300.

The LNA 310 is configured to amplify the RF signal (digital terrestrial broadcast signal RF1). The LNA 310 includes an input matching circuit 320 and an active amplifier circuit 330.

The input matching circuit 320 is configured to convert an input impedance Zai of the downstream active amplifier circuit 330 such that a signal source impedance Zs on the input side of the input terminal 305 is approximately in a complex conjugate relationship with and is matched to an impedance Zii on the input side of the input matching circuit 320. Here, the complex conjugate relationship refers to that each impedance has an equal real part and an imaginary part that is a reactance component equal in magnitude but opposite in sign.

The active amplifier circuit 330 is configured to amplify the signal received from the input matching circuit 320 and supply the amplified signal to the power splitter 400.

The power splitter 400 is configured to split the RF signal received from the LNA 310 into three. The power splitter 400 includes resistive elements 411, 412, and 413 and output matching circuits 420, 430, and 440.

The resistive elements 411, 412, and 413 have their respective one ends commonly connected to an input terminal 405 of the power splitter 400. Furthermore, the resistive element 411 has the other end connected to an input terminal of the output matching circuit 420, and the resistive element 412 has the other end connected to an input terminal of the output matching circuit 430. The resistive element 413 has the other end connected to an input terminal of the output matching circuit 440. The resistive elements 411, 412, and 413 interposed in series are referred to as series resistors.

Interposing such series resistors allows increases in input impedances Zm1, Zm2, and Zm3 as viewed from the output matching circuits 420, 430, and 440. It is therefore possible to achieve, by increasing the impedance conversion ratio of the output matching circuit 420 and the like, wide bandwidth and low loss. Moreover, it is possible to increase the output isolation while reducing the output return loss of the power splitter 400 over a wide bandwidth.

In order to maximize gains and equalize the gains, Zm1, Zm2 and Zm3 are adjusted to approximately the same value. Note that, in order to set the gains of the three signal paths to different values, at least one of the gains can be set to a value different from the others.

Here, in a case where a load impedance of the LNA 310 on the input side of the power splitter 400 is denoted as ZL, this ZL is adjusted to have a complex conjugate relationship with an output impedance Zao of the LNA 310 in order to maximize the gains. That is, the following equation holds:

$$ZL = {Zao}^{⋆} \qquad Equation l$$

Furthermore, the output impedance Zao is adjusted to a relatively small value such as several ohms to several tens of ohms. It is therefore possible to increase the inter-output terminal isolation of the downstream power splitter 400 easily.

Furthermore, an input impedance on the input side of the resistive element 411 is denoted as Zᵢₙ₁, and an input impedance on the input side of the resistive element 412 is denoted as Zᵢₙ₂. An input impedance on the input side of the resistive element 413 is denoted as Zᵢₙ₃. An equivalent impedance of a circuit with the input impedances connected in parallel corresponds to the load impedance ZL described above. Therefore, the following equation holds:

$$1/ZL = {1/Z}_{i n 1} + {1/Z}_{i n 2} + {1/Z}_{i n 3} \qquad Equation 2$$

The output matching circuit 420 converts its load impedance Zo1 into the impedance Zm1 as viewed from the input side of the output matching circuit 420. Here, the impedance Zm1 is approximately in a complex conjugate relationship with an output impedance Zr1 as viewed from the output of the resistive element 411. That is, the following equation holds:

$$Zr 1 = Zm {1}^{⋆} \qquad Equation 3$$

The output impedance Zr1 is represented by the following equation:

$$Zr 1 = Rs 1 + ( {Z}_{in 2} \cdot {Z}_{i n 3} \cdot Zao ) / ( Zao \cdot {Z}_{i n 3} + {Z}_{i n 2} \cdot {Z}_{i n 3} + {Z}_{in 3} \cdot Zao ) \qquad Equation 4$$

In the above equation, Rs1 represents a resistance value of the resistive element 411. Furthermore, the second term on the right side represents an equivalent impedance of the input impedance of each system other than Zᵢₙ₁ and the output impedance Zao of the LNA 310.

Furthermore, the output matching circuit 430 converts its load impedance Zo2 into the impedance Zm2 as viewed from the input side of the output matching circuit 430. The impedance Zm2 is approximately in a complex conjugate relationship with an output impedance Zr2 as viewed from the output of the resistive element 412. That is, the following equation holds:

$$Zr 2 = Zm {2}^{*} \qquad Equation 5$$

The output matching circuit 440 converts its load impedance Zo3 into the impedance Zm3 as viewed from the output matching circuit 440. The impedance Zm3 is approximately in a complex conjugate relationship with an output impedance Zr3 as viewed from the output side of the resistive element 413. That is, the following equation holds:

$$Zr 3 = Zm {3}^{⋆} \qquad Equation 6$$

The output impedances Zr2 and Zr3 are represented by the following equations:

$$Zr 2 = Rs 2 + ( {Z}_{in 1} \cdot {Z}_{i n 3} \cdot Zao ) / ( Zao \cdot {Z}_{i n 3} + {Z}_{i n 1} \cdot {Z}_{i n 3} + {Z}_{in 3} \cdot Zao ) \qquad Equation 7$$

$$Zr 3 = Rs 3 + ( {Z}_{in 1} \cdot {Z}_{i n 2} \cdot Za ) / ( Zao \cdot {Z}_{i n 1} + {Z}_{i n 1} \cdot {Z}_{i n 2} + {Z}_{in 2} \cdot Zao ) \qquad Equation 8$$

In the above equations, Rs2 and Rs3 represents resistance values of the resistive element 412 and 413, respectively.

The resistance values Rs1, Rs2, and Rs3 are adjusted to approximately the same value, for example. Note that at least one of the resistance values can be set to a value different from the others. The same applies to Zᵢₙ₁, Zᵢₙ₂, and Zᵢₙ₃, and Zo1, Zo2, and Zo3.

Note that the output matching circuits 420 and 430 are examples of first and second output matching circuits described in the claims.

Interposing the output matching circuits 420, 430, and 440 allows an increase in gain and a reduction in output return loss. Note that the number of RF signals output from the multi-output LNA 300 is not limited to three. In a case where the number of outputs is other than three, the number of series resistors and the number of output matching circuits are reduced or increased on the basis of the number of outputs.

With the circuit configuration illustrated in the drawing, the following characteristics can be achieved at low cost and with a small circuit area.

1) The input RF signal is amplified with high gain and low noise and distributed to a plurality of receivers (such as the receiver 210).

2) Attenuating a noise signal such as spurious generated in the receiver 210 via the power splitter 400 allows a reduction in interference with the other receivers 220 and 230.

3) Even when the impedance of the receiver fluctuates due to a change in the operating state of the receiver (on/off operation or the like), there is no variation in the characteristics of the multi-output LNA 300, and stable characteristics are provided.

### [Configuration Example of Input Matching Circuit]

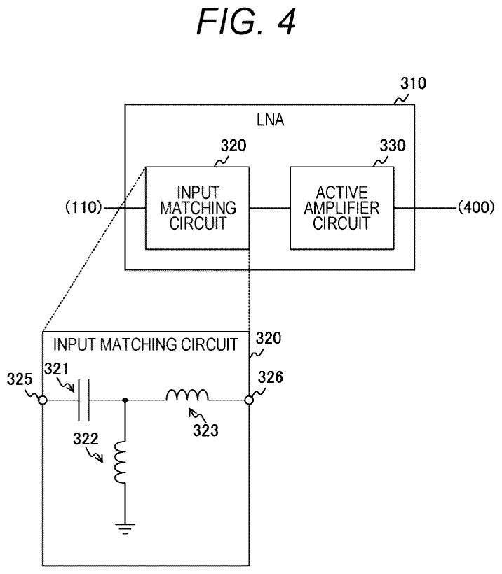

FIG. 4 is a circuit diagram illustrating a configuration example of the input matching circuit 320 according to the first embodiment of the present technology. The input matching circuit 320 includes a capacitive element 321 and inductive elements 322 and 323. The capacitive element 321 and the inductive element 323 are interposed in series, and the inductive element 322 is interposed in parallel. Note that it is also possible to arrange only either the inductive elements or the capacitive element. The connection method, the number, and their respective reactances of the elements are appropriately adjusted so as to achieve impedance matching over the frequency band of the RF signal.

### [Configuration Example of Active Amplifier Circuit]

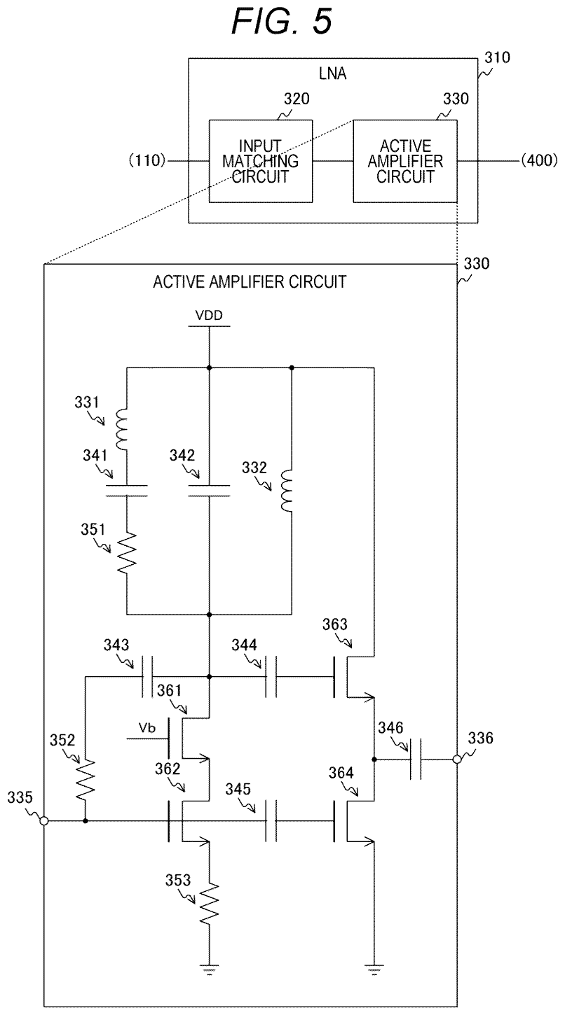

FIG. 5 is a circuit diagram illustrating a configuration example of the active amplifier circuit 330 according to the first embodiment of the present technology. The active amplifier circuit 330 includes inductive elements 331 and 332, capacitive elements 341 to 346, resistive elements 351 to 353, and transistors 361 to 364. As the transistors 361 to 364, for example, n-channel metal oxide semiconductor (nMOS) transistors are used.

The transistor 364 constitutes a common-source amplifier circuit, and a signal from the input terminal 335 is input into a gate of the transistor 364 via the capacitive element 345. The transistor 364 amplifies the input signal and outputs the amplified signal from its drain to an output terminal 336 via the capacitive element 346.

Note that the circuit configuration of the active amplifier circuit 330 is not limited to the configuration illustrated in the drawing as long as the RF signal can be amplified.

### [Configuration Example of Output Matching Circuit]

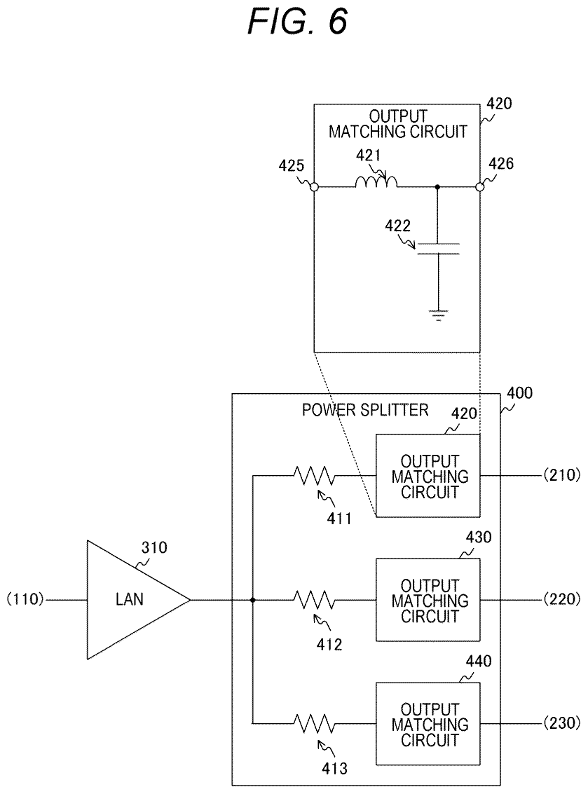

FIG. 6 is a circuit diagram illustrating a configuration example of the output matching circuit 420 according to the first embodiment of the present technology. The output matching circuit 420 includes an inductive element 421 and a capacitive element 422. The inductive element 421 is interposed in series, and the capacitive element 422 is interposed in parallel. The output matching circuits 430 and 440 are similar in configuration to the output matching circuit 420.

Note that it is also possible to arrange only any one of the inductive element, the capacitive element, or the resistive element. The connection method, the number, and their respective reactances of the elements are appropriately adjusted so as to achieve impedance matching over the frequency band of the RF signal.

### [Configuration Example of Receiver]

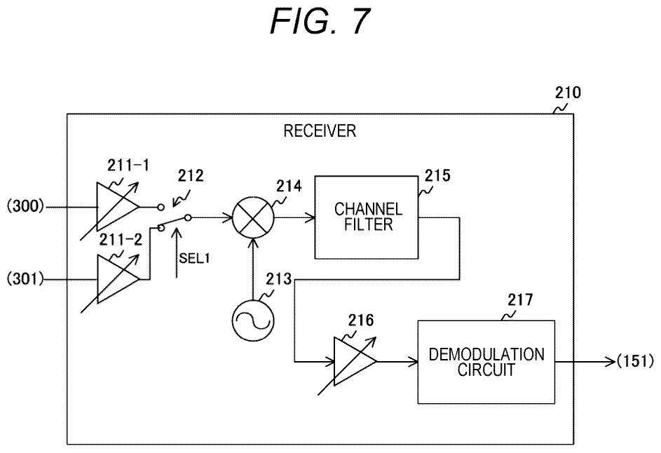

FIG. 7 is a block diagram illustrating a configuration example of the receiver 210 according to the first embodiment of the present technology. The receiver 210 includes a variable amplifier 211-1, a variable amplifier 211-2, a selector 212, a local oscillator 213, a mixer 214, a channel filter 215, a variable amplifier 216, and a demodulation circuit 217.

The variable amplifier 211-1 is configured to amplify the digital terrestrial broadcast signal received from the multi-output LNA 300 and supply the amplified signal to the selector 212. The variable amplifier 211-2 is configured to amplify the satellite broadcast signal received from the multi-output LNA 301 and supply the amplified signal to the selector 212.

The selector 212 is configured to select either the signal received from the variable amplifier 211-1 or the signal received from the variable amplifier 211-2 in accordance with a selection signal SEL1 and output the selected signal to the mixer 214. The local oscillator 213 is configured to generate a local signal of a predetermined frequency and supply the local signal to the mixer 214. The mixer 214 is configured to combine the RF signal received from the variable amplifier 212 and the local signal and supply the combined signal to the channel filter 215 as an intermediate frequency signal.

The channel filter 215 is configured to extract a signal of a predetermined channel from the intermediate frequency signal or the baseband signal and supply the extracted signal to the variable amplifier 216. The variable amplifier 216 is configured to amplify the signal received from the channel filter 215 and supply the amplified signal to the demodulation circuit 217.

The demodulation circuit 217 is configured to demodulate the signal received from the variable amplifier 216 and supply the demodulated signal to the post-stage circuit 151.

Here, consider a configuration where an output matching circuit is additionally provided in the LNA 310 and a Wilkinson splitter is used as the power splitter 400 as a comparative example.

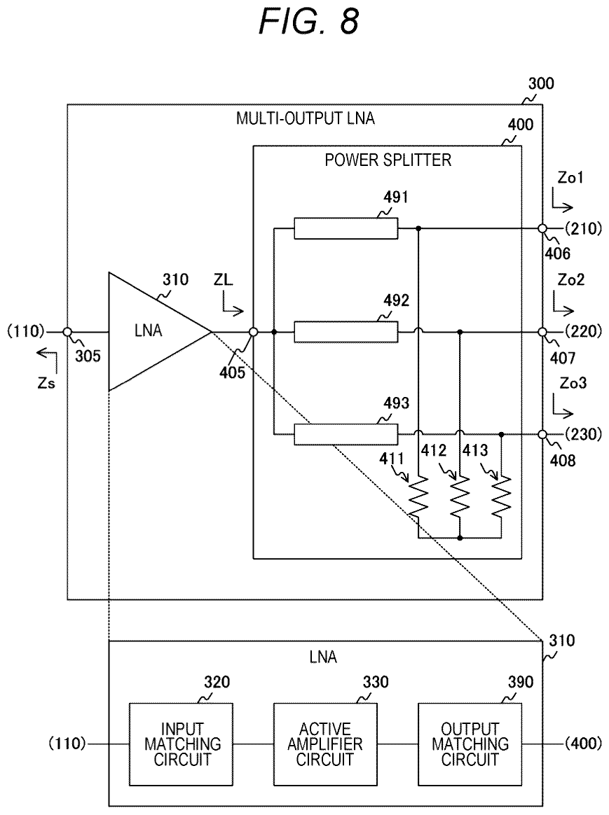

FIG. 8 is a block diagram illustrating a configuration example of a multi-output LNA according to the comparative example. In the comparative example, an output matching circuit 390 is additionally provided in the LNA 310. Furthermore, transmission lines 491 to 493 and resistive elements 411 to 413 are arranged in the power splitter 400.

The transmission lines 491 to 493 have their respective one ends commonly connected to the input terminal 405 and have the other ends connected to output terminals 406 to 408, respectively. A length of each of the transmission lines 491 to 493 is set to ¼ wavelength.

The resistive elements 411 to 413 have their respective one ends connected to each other and have the other ends connected to the output terminals 406 to 408, respectively. The power splitter 400 illustrated in the drawing is referred to as Wilkinson splitter.

In a case where the frequency of the RF signal is in the range of 1 to 3 gigahertz (GHz), the ¼ wavelength (in other words, 90-degree electrical length) becomes about 20 millimeters (mm), and the circuit area becomes very large accordingly. The increase in the circuit area leads to disadvantages in terms of cost in circuit integration.

On the other hand, in the first embodiment of the present technology, the output matching circuits 420, 430, and 440 are arranged in the power splitter 400, which eliminates the need of the transmission line of ¼ wavelength and allows reductions in circuit area and cost as compared with the comparative example.

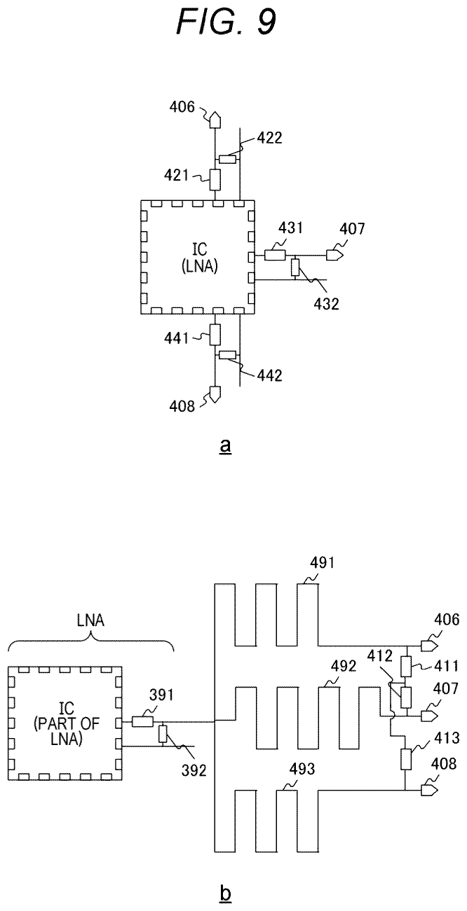

FIG. 9 is a diagram for comparing a footprint of the first embodiment of the present technology with a footprint the comparative example. Of the drawing, a is a diagram illustrating an implementation example of the multi-output LNA 300 of the first embodiment. Of the drawing, b is a diagram illustrating an implementation example of the multi-output LNA 300 of the comparative example.

As illustrated in a of the drawing, the LNA 310 is integrated into an integrated circuit (IC). The inductive element 421 is interposed between the output terminal 406 and the IC (LNA 310), and the capacitive element 422 has one end connected to the output terminal 406. The inductive element 421 and the capacitive element 422 function as the output matching circuit 420.

Furthermore, the inductive element 431 is interposed between the output terminal 407 and the IC, and the capacitive element 432 has one end connected to the output terminal 407. The inductive element 431 and the capacitive element 432 function as the output matching circuit 430. The inductive element 441 is interposed between the output terminal 408 and the IC, and the capacitive element 442 has one end connected to the output terminal 408. The inductive element 441 and the capacitive element 442 function as the output matching circuit 440.

On the other hand, in the comparative example, as illustrated in b of the drawing, the input matching circuit 320 and the active amplifier circuit 330 in the LNA 310 are integrated into an IC, and an inductive element 391 and a capacitive element 392 in the output matching circuit 390 are arranged outside the IC.

Furthermore, the transmission lines 491 to 493 have their one ends commonly connected to the IC via the inductive element 391 and have the other ends connected to the output terminals 406 to 408, respectively. The resistive elements 411 to 413 have their respective one ends connected to each other and have the other ends connected to the output terminals 406 to 408, respectively.

As illustrated in a and b of the drawing, in a case where the input matching circuit 320 and the active amplifier circuit 330 are integrated into an IC, the footprint outside the IC in the first embodiment becomes about ⅓ of the footprint in the comparative example.

In a of the drawing, the inductive elements 421, 431, and 441 and the capacitive elements 422, 432, and 442 are arranged outside the IC in order to reduce a loss. In a case where it is not necessary to prioritize low loss, it is also possible to integrate such elements into the IC. In this case, the circuit area outside the IC can be reduced to 1/7 of the circuit area of the comparative example. Note that it is not feasible to integrate the transmission line 491 and the like of the comparative example into the IC in a gigahertz (GHz) frequency range.

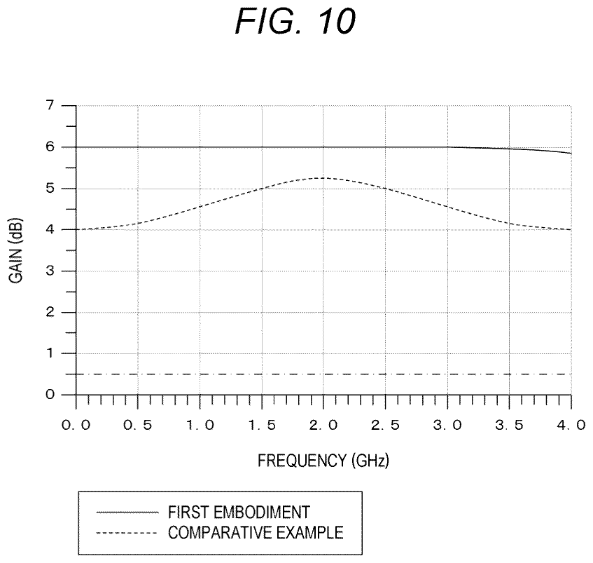

FIG. 10 is a graph showing an example of a gain by frequency according to the first embodiment of the present technology and the comparative example. In the drawing, the vertical axis represents the gain, and the horizontal axis represents the frequency. Furthermore, the solid line indicates the characteristics of the multi-output LNA 300 of the first embodiment, and the dotted line indicates the characteristics of the comparative example.

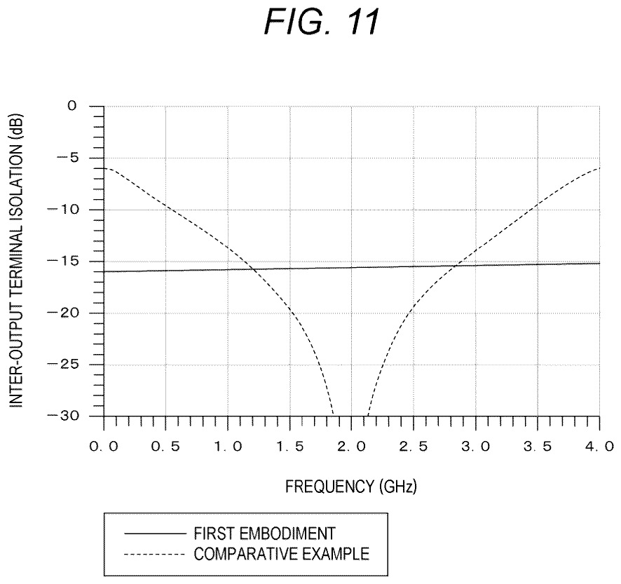

FIG. 11 is a graph showing an example of inter-output terminal isolation by frequency according to the first embodiment of the present technology and the comparative example. In the drawing, the vertical axis represents the inter-output terminal isolation, and the horizontal axis represents the frequency. Furthermore, the solid line indicates the characteristics of the multi-output LNA 300 of the first embodiment, and the dotted line indicates the characteristics of the comparative example.

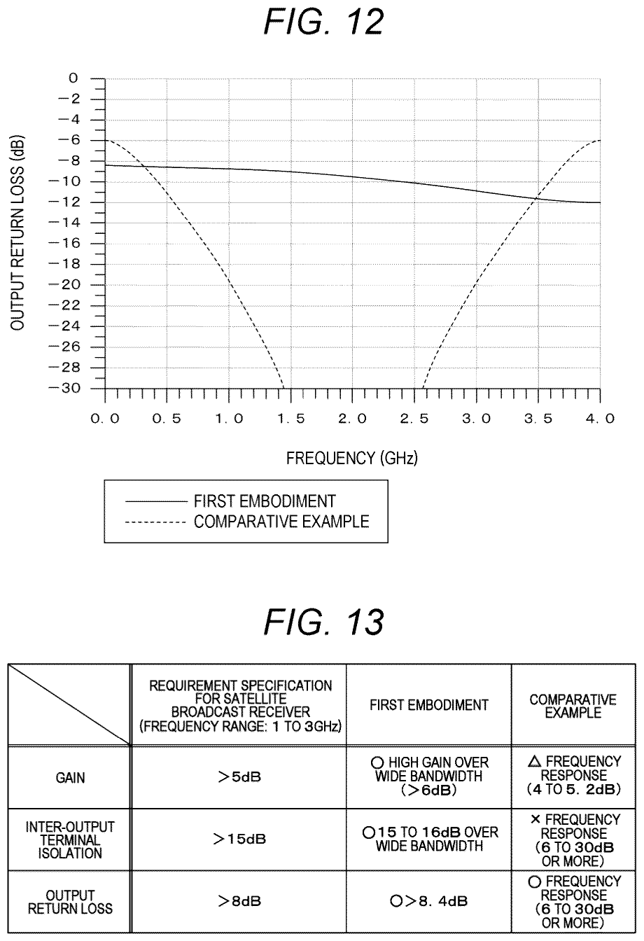

FIG. 12 is a graph showing an example of an output return loss by frequency according to the first embodiment of the present technology and the comparative example. In the drawing, the vertical axis represents the output return loss, and the horizontal axis represents the frequency. Furthermore, the solid line indicates the characteristics of the multi-output LNA 300 of the first embodiment, and the dotted line indicates the characteristics of the comparative example.

FIG. 13 is a diagram showing a comparison result of characteristics between the first embodiment of the present technology and the comparative example. As shown in FIG. 10, in the first embodiment, a high gain can be achieved over a wide bandwidth. On the other hand, in the comparative example, the gain fluctuates in a manner that depends on the frequency.

Furthermore, as shown in FIG. 11, in the first embodiment, high inter-output terminal isolation can be achieved over a wide bandwidth. On the other hand, in the comparative example, the inter-output terminal isolation fluctuates in a manner that depends on the frequency.

Furthermore, as shown in FIG. 12, the output return loss can be sufficiently reduced in the first embodiment. In the comparative example, the output return loss can also be reduced, but in a manner that depends on the frequency.

As described above, according to the first embodiment of the present technology, since the output matching circuits 420, 430, and 440 are provided in the power splitter 400, the circuit area and the cost can be reduced as compared with a case where the Wilkinson splitter is used.

### 2. Second Embodiment

In the first embodiment described above, the resistive elements 411 to 413 are provided in the power splitter 400, but the resistive elements can be removed. A reception device 150 of this second embodiment is different from the reception device 150 of the first embodiment in that the resistive elements 411 to 413 are removed.

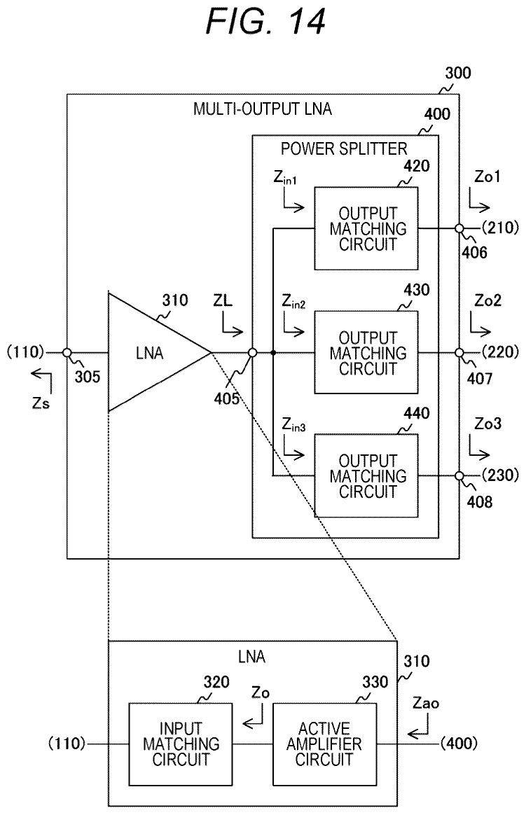

FIG. 14 is a block diagram illustrating a configuration example of a multi-output LNA 300 according to the second embodiment of the present technology. The multi-output LNA 300 of this second embodiment is different from the multi-output LNA 300 of the first embodiment in that the resistive elements 411 to 413 are not arranged.

The output matching circuits 420, 430, and 440 have their respective input terminals commonly connected to the output terminal of the LNA 310. Furthermore, the output matching circuit 420 converts its load impedance Zo1 into the impedance Zin1 as viewed from the input side of the output matching circuit 420. Similarly, the impedances Zo2 and Zo3 are converted into the impedances Zᵢₙ₂ and Zᵢₙ₃ as viewed from the input side of the output matching circuits 430 and 440, respectively. The impedances Zin1, Zin2, and Zin3 are matched to the impedance Zao as viewed from the output side of the active amplifier circuit as in the follow equation, and the following equation holds.

$$1/Z L = {1/Z}_{in 1} + {1/Z}_{in 2} + {1/Z}_{i n 3} = {( 1/Z ao )}^{⋆} \qquad Equation 9$$

As described above, according to the second embodiment of the present technology, since the resistive elements 411 to 413 are removed, the circuit scale and cost can be further reduced. Since the resistive elements are removed, the inter-output terminal isolation characteristics and the output return loss are compromised, but the gain increases, as compared with the first example.

### 3. Third Embodiment

In the first embodiment described above, the resistive elements 411 to 413 are interposed on the input side of the output matching circuit 420 and the like, but it is also possible to interpose the resistive elements 411 to 413 on the output side. A reception device 150 of this second embodiment is different from the reception device 150 of the first embodiment in that the resistive elements 411 to 413 are interposed on the output side.

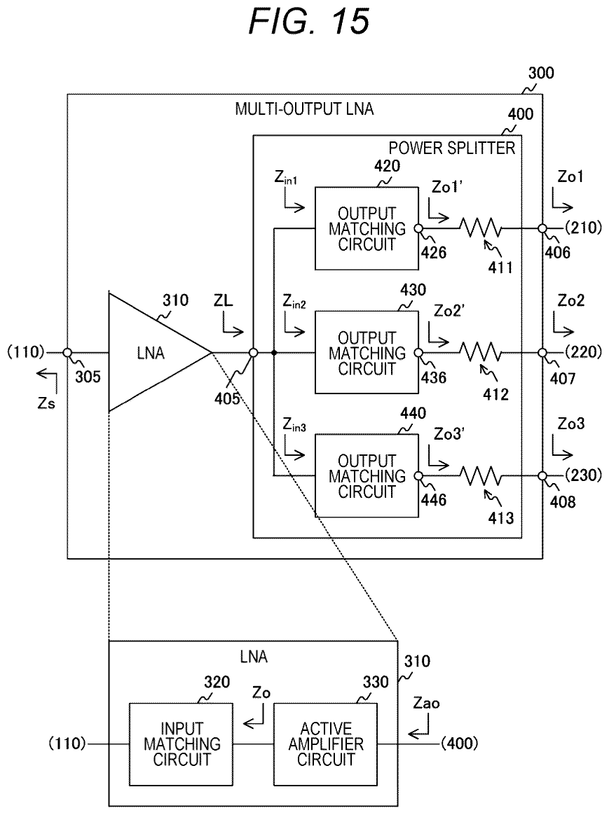

FIG. 15 is a block diagram illustrating a configuration example of a multi-output LNA 300 according to a third embodiment of the present technology. The multi-output LNA 300 of this third embodiment is different from the multi-output LNA 300 of the first embodiment in that the resistive elements 411, 412, and 413 are interposed between the output matching circuits 420, 430, and 440 and the output terminals 406, 407, and 408.

An output impedance on the output side of an output terminal 426 of the output matching circuit 420 is denoted as Zo1′. The output matching circuit 420 converts its load impedance Zo1′ into the impedance Zin1 as viewed from the input side of the output matching circuit 420. The impedances Zin1, Zin2, and Zin3 are matched to the impedance Zao as viewed from the output side of the active amplifier circuit 330 as in the follow equation, and Equation 9 holds.

Similarly, the output matching circuits 430 and 440 convert their respective load impedances Zo2′ and Zo3′ into the impedances Zin2 and Zin3 as viewed from the input side of the output matching circuits 430 and 440. The impedances Zin2 and Zin3 satisfy Equation 9. With this configuration illustrated in the drawing, the output return loss can be reduced as compared with the first embodiment.

As described above, according to the third embodiment of the present technology, since the resistive elements 411 to 413 are interposed on the output side, the output return loss can be reduced. As compared with the first example, the impedance conversion ratio of the output matching circuit becomes high, which leads to disadvantages in terms of loss in and wideband characteristics of the output matching circuit.

### 4. Fourth Embodiment

In the first embodiment described above, the multi-output LNA 300 is arranged in the reception device 150 that is responsible only for receiving the RF signal, but the multi-output LNA 300 may be arranged in a device that is responsible for both transmitting and receiving the RF signal. This fourth embodiment is different from the first embodiment in that the multi-output LNA 300 is provided in a device that is responsible for both transmitting and receiving the RF signal.

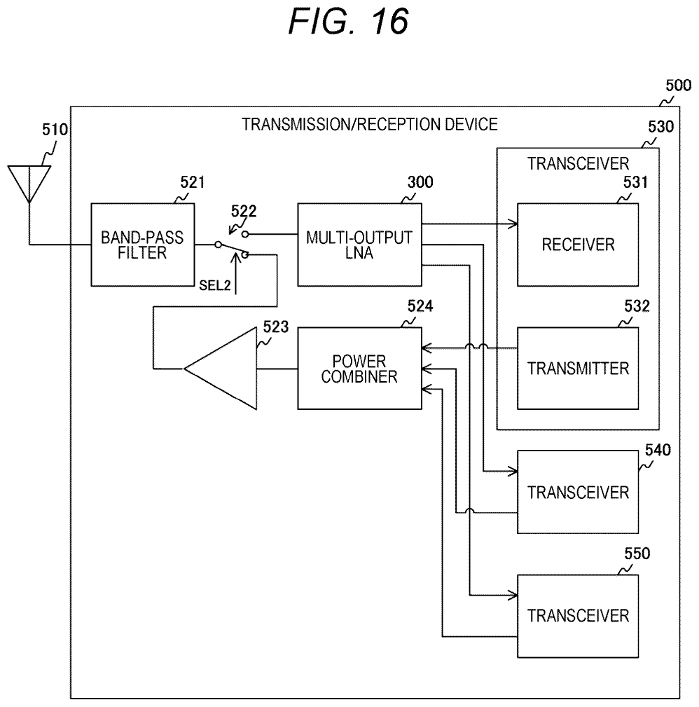

FIG. 16 is a block diagram illustrating a configuration example of a transmission/reception device 500 according to the fourth embodiment of the present technology. The transmission/reception device 500 is a device used for a relatively broadband wireless local area network (WLAN), and includes an antenna 510, a band-pass filter 521, a selector 522, and the multi-output LNA 300. The transmission/reception device 500 further includes a power amplifier 523, a power combiner 524, and transceivers 530, 540, and 550.

The antenna 510 is configured to convert an electromagnetic wave into an electric signal, and vice versa. The band-pass filter 521 is configured to cause a component of a predetermined frequency band to pass through. The selector 522 is configured to select either the input terminal of the multi-output LNA 300 or the output terminal of the power amplifier 523 in accordance with a selection signal SEL2 and connect the selected terminal to the antenna 510 via the band-pass filter 521.

Note that one antenna 510 is shared by the transmitter and the receiver, or alternatively, both a transmission antenna and a reception antenna may be provided. This configuration eliminates the need of the selector 522. In a case where the transmission frequency and the reception frequency are different, the selector 522 may be replaced with a duplexer.

The multi-output LNA 300 of the fourth embodiment is similar in configuration to the first embodiment. This multi-output LNA 300 distributes the RF signal received from the selector 522 to the transceivers 530, 540, and 550.

The transceiver 530 is configured to perform demodulation processing or modulation processing on the RF signal. The transceiver 530 includes a receiver 531 and a transmitter 532. The receiver 531 is configured to demodulate the RF signal. The transmitter 532 is configured to perform modulation processing on the basis of transmit data to generate a transmit RF signal as a transmit signal. The transmitter 532 supplies the transmit signal to the power combiner 524. The transceivers 540 and 550 are similar in configuration to the transceiver 530.

The power combiner 524 is configured to combine the transmit signals received from the transceivers 530, 540, and 550 and supply the combined signal to the power amplifier 523. The power amplifier 523 is configured to amplify the signal received from the power combiner 524 and supply the amplified signal to the selector 522.

As illustrated in the drawing, applying the multi-output LNA 300 to the transmission/reception device 500 allows the transmission/reception device 500 to simultaneously receive a plurality of channels.

Note that the second embodiment or the third embodiment can be applied to the fourth embodiment.

As described above, according to the fourth embodiment of the present technology, since the multi-output LNA 300 is arranged in the transmission/reception device 500, a plurality of channels can be simultaneously received.

### 5. Example of Application to Mobile Body

The technology according to the present disclosure (the present technology) can be applied to various products. For example, the technology according to the present disclosure may be implemented as a device mounted on any type of mobile body such as an automobile, an electric vehicle, a hybrid electric vehicle, a motorcycle, a bicycle, a personal mobility, an airplane, a drone, a vessel, and a robot.

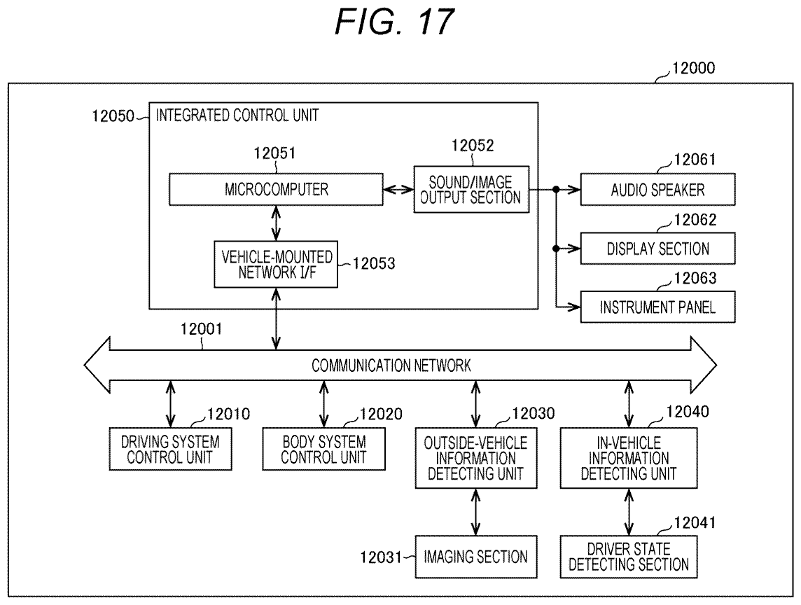

FIG. 17 is a block diagram illustrating a schematic configuration example of a vehicle control system that is an example of a mobile body control system to which the technology according to the present disclosure can be applied.

The vehicle control system 12000 includes a plurality of electronic control units connected to each other via a communication network 12001. In the example illustrated in FIG. 17, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as functional components of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 17, as the output device, an audio speaker 12061, a display section 12062, and an instrument panel 12063 are illustrated. The display section 12062 may, for example, include at least one of an on-board display and a head-up display.

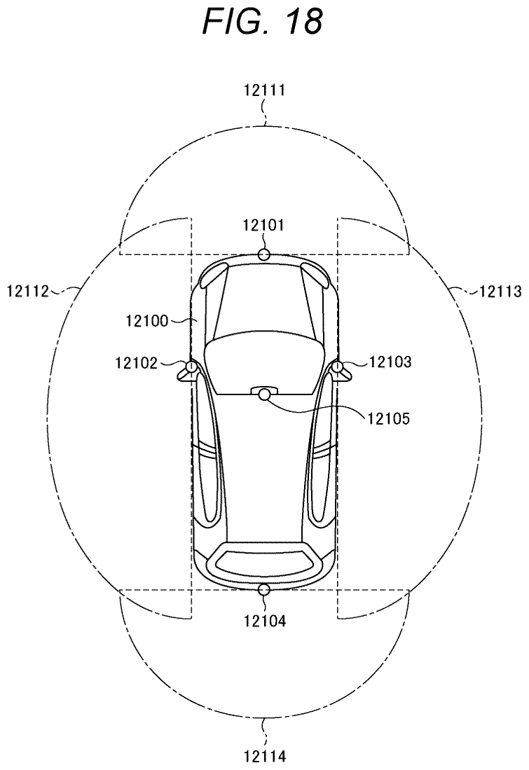

FIG. 18 is a diagram illustrating an example of an installation position of the imaging section 12031.

In FIG. 18, the imaging section 12031 includes imaging sections 12101, 12102, 12103, 12104, and 12105.

The imaging sections 12101, 12102, 12103, 12104, 12105 are provided, for example, at positions such as a front nose, sideview mirrors, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 18 illustrates examples of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the sound/image output section 12052 among the configurations described above. Specifically, the reception device 150 in FIG. 1 can be applied to the sound/image output section 12052. It is possible to reduce, by applying the technology according to the present disclosure to the sound/image output section 12052, the circuit area and cost of the device.

Note that the above-described embodiments show examples for embodying the present technology, and the matters in the embodiments and the matters specifying the invention in the claims have a corresponding relationship. Similarly, the matters specifying the invention in the claims and the matters with the same names in the embodiments of the present technology have correspondence relationships. However, the present technology is not limited to the embodiments, and can be embodied by applying various modifications to the embodiments without departing from the scope of the present technology.

Note that the effects described herein are merely examples and are not limited, and other effects may also be achieved.

Note that the present technology may also have the following configuration.

(1) A distribution circuit including:
a low noise amplifier including an input matching circuit that converts an input impedance of a downstream circuit, and an amplifier circuit that amplifies a wireless signal received from the input matching circuit; and
a power splitter including a first output matching circuit that converts a first load impedance into a first impedance related to a load impedance ZL of the low noise amplifier, and a second output matching circuit that converts a second load impedance into a second impedance related to the ZL.

(2) The distribution circuit according to the above (1), in which
the power splitter further includes:
a first resistive element interposed between an output terminal of the low noise amplifier and an input terminal of the first output matching circuit; and
a second resistive element interposed between the output terminal of the low noise amplifier and an input terminal of the second output matching circuit,
the ZL is approximately in a complex conjugate relationship with an output impedance Zao of the low noise amplifier,
the ZL corresponds to an equivalent impedance of a circuit in which a predetermined number of input impedances including a first input impedance Zᵢₙ₁ and a second input impedance Zᵢₙ₂ are connected in parallel,
the first impedance is approximately in a complex conjugate relationship with an output impedance Zr1 as viewed from output of the first resistive element, and
the Zr1 corresponds to a sum of a resistance value of the first resistive element and an equivalent impedance of an input impedance of each system other than the Zᵢₙ₁ and the Zao,
the second impedance is approximately in a complex conjugate relationship with an output impedance Zr2 as viewed from output of the second resistive element, and
the Zr2 corresponds to a sum of a resistance value of the second resistive element and an equivalent impedance of an input impedance of each system other than the Zᵢₙ₂ and the Zao.

(3) The distribution circuit according to the above (1), in which
the low noise amplifier has an output terminal connected to both input terminals of the first and second output matching circuits,
the ZL is approximately in a complex conjugate relationship with an output impedance Zao of the low noise amplifier,
the ZL corresponds an equivalent impedance of a circuit in which a predetermined number of input impedances including a first input impedance Zᵢₙ₁ and a second input impedance Zᵢₙ₂ are connected in parallel,
the first impedance corresponds to the Zᵢₙ₁, and
the second impedance corresponds to the Zᵢₙ₂.

(4) The distribution circuit according to claim 3, in which
the power splitter further includes:
a first resistive element having one end connected to an output terminal of the first output matching circuit; and
a second resistive element having one end connected to an output terminal of the second output matching circuit.

(5) The distribution circuit according to any one of the above (1) to (4), in which
the first and second output matching circuits each include at least one of an inductive element, a capacitive element, or a resistive element.

(6) A reception device including:
a low noise amplifier including an input matching circuit that converts an input impedance of a downstream circuit, and an amplifier circuit that amplifies a wireless signal received from the input matching circuit;
a power splitter including a first output matching circuit that converts a first load impedance into a first impedance related to a load impedance ZL of the low noise amplifier, and a second output matching circuit that converts a second load impedance into a second impedance related to the ZL;
a first receiver that demodulates a signal output from an output terminal of the first output matching circuit; and
a second receiver that demodulates a signal output from an output terminal of the second output matching circuit.

(7) A transmission/reception device including:
a low noise amplifier including an input matching circuit that converts an input impedance of a downstream circuit, and an amplifier circuit that amplifies a wireless signal received from the input matching circuit;
a power splitter including a first output matching circuit that converts a first load impedance into a first impedance related to a load impedance ZL of the low noise amplifier, and a second output matching circuit that converts a second load impedance into a second impedance related to the ZL;
a first receiver that demodulates a signal output from an output terminal of the first output matching circuit;
a second receiver that demodulates a signal output from an output terminal of the second output matching circuit; and
a transmitter that generates a transmit signal.

### REFERENCE SIGNS LIST

100 Reception system
110, 120, 510 Antenna
150 Reception device
151 Post-stage circuit
200 Multi-tuner
210, 220, 230, 531 Receiver
212, 522 Selector
211-1, 211-2, 216 Variable amplifier
213 Local oscillator
214 Mixer
215 Channel filter
217 Demodulation circuit
300, 301 Multi-output LNA
310 LNA
320 Input matching circuit
321, 341 to 346, 392, 422, 432, 442 Capacitive element
322, 323, 331, 332, 391, 421, 431, 441 Inductive element
330 Active amplifier circuit
351 to 353, 411 to 413 Resistive element
361 to 364 Transistor
390, 420, 430, 440 Output matching circuit
400 Power splitter
491 to 493 Transmission line
500 Transmission/reception device
521 Band-pass filter
523 Power amplifier
524 Power combiner
530, 540, 550 Transceiver
532 Transmitter
12052 Sound/image output section

1. A distribution circuit comprising:
a low noise amplifier including an input matching circuit that converts an input impedance of a downstream circuit, and an amplifier circuit that amplifies a wireless signal received from the input matching circuit; and
a power splitter including a first output matching circuit that converts a first load impedance into a first impedance related to a load impedance ZL of the low noise amplifier, and a second output matching circuit that converts a second load impedance into a second impedance related to the ZL.

2. The distribution circuit according to claim 1, wherein
the power splitter further includes:
a first resistive element interposed between an output terminal of the low noise amplifier and an input terminal of the first output matching circuit; and
a second resistive element interposed between the output terminal of the low noise amplifier and an input terminal of the second output matching circuit,
the ZL is approximately in a complex conjugate relationship with an output impedance Zao of the low noise amplifier,
the ZL corresponds to an equivalent impedance of a circuit in which a predetermined number of input impedances including a first input impedance Zᵢₙ₁ and a second input impedance Zᵢₙ₂ are connected in parallel,
the first impedance is approximately in a complex conjugate relationship with an output impedance Zr1 as viewed from output of the first resistive element,
the Zr1 corresponds to a sum of a resistance value of the first resistive element and an equivalent impedance of an input impedance of each system other than the Zᵢₙ₁ and the Zao,
the second impedance is approximately in a complex conjugate relationship with an output impedance Zr2 as viewed from output of the second resistive element, and
the Zr2 corresponds to a sum of a resistance value of the second resistive element and an equivalent impedance of an input impedance of each system other than the Zᵢₙ₂ and the Zao.

3. The distribution circuit according to claim 1, wherein
the low noise amplifier has an output terminal connected to both input terminals of the first and second output matching circuits,
the ZL is approximately in a complex conjugate relationship with an output impedance Zao of the low noise amplifier,
the ZL corresponds an equivalent impedance of a circuit in which a predetermined number of input impedances including a first input impedance Zᵢₙ₁ and a second input impedance Zᵢₙ₂ are connected in parallel,
the first impedance corresponds to the Zᵢₙ₁, and
the second impedance corresponds to the Zᵢₙ₂.

4. The distribution circuit according to claim 3, wherein
the power splitter further includes:
a first resistive element having one end connected to an output terminal of the first output matching circuit; and
a second resistive element having one end connected to an output terminal of the second output matching circuit.

5. The distribution circuit according to claim 1, wherein
the first and second output matching circuits each include at least one of an inductive element, a capacitive element, or a resistive element.

6. A reception device comprising:
a low noise amplifier including an input matching circuit that converts an input impedance of a downstream circuit, and an amplifier circuit that amplifies a wireless signal received from the input matching circuit;
a power splitter including a first output matching circuit that converts a first load impedance into a first impedance related to a load impedance ZL of the low noise amplifier, and a second output matching circuit that converts a second load impedance into a second impedance related to the ZL;
a first receiver that demodulates a signal output from an output terminal of the first output matching circuit; and
a second receiver that demodulates a signal output from an output terminal of the second output matching circuit.

7. A transmission/reception device comprising:
a low noise amplifier including an input matching circuit that converts an input impedance of a downstream circuit, and an amplifier circuit that amplifies a wireless signal received from the input matching circuit;
a power splitter including a first output matching circuit that converts a first load impedance into a first impedance related to a load impedance ZL of the low noise amplifier, and a second output matching circuit that converts a second load impedance into a second impedance related to the ZL;
a first receiver that demodulates a signal output from an output terminal of the first output matching circuit;
a second receiver that demodulates a signal output from an output terminal of the second output matching circuit; and
a transmitter that generates a transmit signal.
